(19) United States
(12) Patent Application Publication
(10) Pub. No.: US 2012/0204960 A1
(43) Pub. Date: Aug. 16, 2012

(54) ORGANIC PHOTOVOLTAIC CELL AND METHOD FOR MANUFACTURING THE SAME

(76) Inventors: Takehito Kato, Oyama-shi (JP); Akiko Mitani, Tsukuba-shi (JP); Toshihiro Ohnishi, Tsukuba-shi (JP)

(21) Appl. No.: 13/503,620

(22) PCT Filed: Oct. 26, 2010
(86) PCT No.: PCT/JP2010/068943

§ 371 Date: Apr. 23, 2012

(30) Foreign Application Priority Data
Oct. 30, 2009 (JP) 2009-250583

(51) Int. Cl. H01L 51/44; H01L 51/48

(52) U.S. Cl. 136/263; 438/82; 257/E51.012

(57) ABSTRACT

An organic photovoltaic cell including an anode, a cathode, and an organic active layer provided between the anode and the cathode and formed by using a solution containing a first p-type semiconductor material, an n-type semiconductor material and a solvent, wherein a difference between a solubility parameter of the first p-type semiconductor material and a solubility parameter of the solvent is from 2.9 to 6.5, and a difference between a solubility parameter of the n-type semiconductor material and the solubility parameter of the solvent is from 0 to 5. The organic photovoltaic cell of the present invention has high photovoltaic efficiency.

### TECHNICAL FIELD

The present invention relates to an organic photovoltaic cell used in organic photovoltaic devices such as organic solar cells and organic optical sensors, and a method for manufacturing the same.

### BACKGROUND ART

An organic photovoltaic cell is a cell comprising a pair of electrodes consisting of an anode and a cathode and an organic active layer provided between the pair of electrodes. In an organic photovoltaic cell, one electrode is made of a transparent material. Light is entered from the transparent electrode side and is incident on the organic active layer. The energy (hv) of light incident on the organic active layer generates charges (holes and electrons) in the organic active layer. The generated holes move toward the anode and the electrons move toward the cathode. As a consequence, when an external circuit is connected to the electrodes, current (I) is supplied to the external circuit.

The organic active layer comprises an electron-acceptor compound (n-type semiconductor) and an electron-donor compound (p-type semiconductor). In some cases, the electron-acceptor compound (n-type semiconductor) and the electron-donor compound (p-type semiconductor) are mixed and used to form an organic active layer of single layer structure. In the other cases, an electron-acceptor layer comprising the electron-acceptor compound and an electron-donor layer comprising the electron-donor compound are joined to form an organic active layer of two-layer structure (see, e.g., Patent Document 1).

Usually, the former organic active layer of single layer structure is referred to as a bulk hetero type organic active layer, and the latter organic active layer of two-layer structure is referred to as a heterojunction type organic active layer.

In the former bulk hetero type organic active layer, the electron-acceptor compound and the electron-donor compound form phases of fine and complicated shapes extending continuously from one electrode side to the other electrode side, and form complicated interfaces with being separated from each other. In other words, in the bulk hetero type organic active layer, a phase comprising the electron-acceptor compound and a phase comprising the electron-donor compound are in contact with each other via interfaces of an extremely large area. Consequently, an organic photovoltaic cell having the bulk hetero type organic active layer accomplishes a higher photovoltaic efficiency than an organic photovoltaic cell having the heterojunction type organic active layer, in which a layer comprising the electron-acceptor compound and a layer comprising the electron-donor compound are in contact with each other via a single flat interface.

### RELATED ART DOCUMENTS

### Patent Documents

Patent Document 1: JP 2009-084264 A

### SUMMARY OF THE INVENTION

Besides the above mentioned organic photovoltaic cells, there is another type of photovoltaic cell, i.e., an inorganic photovoltaic cell having an active layer made from an inorganic semiconductor material such as crystalline silicon and amorphous silicon. The organic photovoltaic cell has advantages over the inorganic photovoltaic cell in that the organic active layer can be easily manufactured at room temperature by an applying method or the like, and that it is light-weight, for example. The organic photovoltaic cell, however, has a drawback in that its photovoltaic efficiency is low.

There is an overriding demand for improving photovoltaic efficiency of photovoltaic cells, whether organic or inorganic. Particularly, there is a demand today for further improving photovoltaic efficiency of the organic photovoltaic cell because it has an advantage in terms of manufacture.

The present invention has been made in view of the conventional circumstances and its object is to provide an organic photovoltaic cell having a high photovoltaic efficiency and a method for manufacturing the same.

In order to solve the above-mentioned problem, the present invention provides an organic photovoltaic cell having the following structure and a method for manufacturing the same.

[1] An organic photovoltaic cell comprising:

an anode;

a cathode; and

an organic active layer provided between the anode and the cathode and formed by using a solution comprising a first p-type semiconductor material, an n-type semiconductor material and a solvent, wherein

a difference between a solubility parameter of the first p-type semiconductor material and a solubility parameter of the solvent is from 2.9 to 6.5, and a difference between a solubility parameter of the n-type semiconductor material and the solubility parameter of the solvent is from 0 to 5.

[2] The organic photovoltaic cell according to [1], wherein a second p-type semiconductor material is included as another p-type semiconductor material that constitutes the organic active layer, and a difference between a solubility parameter of the second p-type semiconductor material and the solubility parameter of the solvent is from 2.8 to 6.5.

[3] The organic photovoltaic cell according to [2], wherein a weight of the second p-type semiconductor material is 50 or less when a total weight of the p-type semiconductor materials included in the organic active layer is taken as 100.

[4] A method for manufacturing an organic photovoltaic cell that comprises an anode, a cathode, and an organic active layer provided between the anode and the cathode and formed by using a solution comprising a first p-type semiconductor material, an n-type semiconductor material and a solvent, the method comprising:

selecting the first p-type semiconductor material, the n-type semiconductor material and the solvent such that a difference between a solubility parameter of the first p-type semiconductor material and a solubility parameter of the solvent is from 2.9 to 6.5 and a difference between a solubility parameter of the n-type semiconductor material and the solubility parameter of the solvent is from 0 to 5.

[5] The method for manufacturing an organic photovoltaic cell according to [4], wherein a second p-type semiconductor material is used as another p-type semiconductor material that constitutes the organic active layer, and the method comprises selecting the first p-type semiconductor material, the second p-type semiconductor material, the n-type semiconductor material and the solvent such that a difference between a solubility parameter of the second p-type semiconductor material and the solubility parameter of the solvent is from 2.8 to 6.5.

[6] The method for manufacturing an organic photovoltaic cell according to [5], wherein a weight of the second p-type semiconductor material is adjusted to be 50 or less when a total weight of the p-type semiconductor materials included in the organic active layer is taken as 100.

### BRIEF DESCRIPTION OF THE DRAWING

FIG. 1 is a cross sectional schematic view of an organic photovoltaic cell showing a phase separation structure of the bulk hetero type active layer.

### EXPLANATIONS OF LETTERS OR NUMERALS

1 Organic active layer
2 Transparent first electrode (anode)
3 Second electrode (cathode)
4 First intermediate layer (hole transport layer)
5 Second intermediate layer (electron transport layer)
6 P-type region
7 N-type region
8 Interfacial region

### EMBODIMENTS FOR CARRYING OUT THE INVENTION

As mentioned above, the organic photovoltaic cell of the present invention comprises an anode, a cathode, and an organic active layer provided between the anode and the cathode and formed by using a solution comprising a first p-type semiconductor material, an n-type semiconductor material and a solvent, and is characterized in that a difference between a solubility parameter of the first p-type semiconductor material and the solubility parameter of the solvent is from 2.9 to 6.5, and that a difference between a solubility parameter of the n-type semiconductor material and the solubility parameter of the solvent is from 0 to 5.

In the present invention, a second p-type semiconductor material may be included as another p-type semiconductor material that constitutes the organic active layer. In such a case, a difference between a solubility parameter of the second p-type semiconductor material and the solubility parameter of the solvent is from 2.8 to 6.5.

The solubility parameter (δ:SP value) is a parameter defined by the regular solution theory introduced by Hildebrand and is known to provide a measure of solubility of a two-component solution. The regular solution theory assumes that only intermolecular forces act between a solvent and a solute, and the solubility parameter is used as a measure of the degree of intermolecular forces. Although actual solutions are not always regular solutions, it is empirically known that the smaller the difference between the solubility parameters of two components is, the higher the solubility is.

According to findings of the present inventors, when a solution comprising a p-type semiconductor material, an n-type semiconductor material and a solvent is used to obtain a bulk hetero type organic active layer, setting the differences between the solubility parameters of the above-mentioned three components to predetermined ranges enables to select the most suitable solvent to obtain a bulk hetero type active layer with the most suitable phase separation structure, i.e., a bulk hetero type active layer with increased total volume of an interfacial region between the p-type region and the n-type region (an electron-hole exciton generating region and an electron and hole transfer pass region).

Accordingly, when a desired p-type and n-type semiconductor materials are selected on the basis of light absorption wavelength range required for an intended cell, the most suitable solvent can be selected to obtain a bulk hetero type active layer with the most suitable phase separation structure, i.e., a bulk hetero type active layer with increased total area of the interface between the p-type region and the n-type region. This effect can be achieved when two or more materials are used as the p-type semiconductor material. Therefore, even when two or more p-type semiconductor materials having different light absorption edge wavelengths are selected in order to widen light absorption wavelength range for improved photovoltaic efficiency, the most suitable solvent can also be selected, which allows preparation of a bulk hetero type active layer with the most suitable phase separation structure.

Thus, the organic photovoltaic cell and the method for manufacturing the same of the present invention allow efficient manufacture of an organic photovoltaic cell having high photovoltaic efficiency.

The components of the organic photovoltaic cell of the present invention, including an anode, an organic active layer, a cathode, and other components formed as required, and materials for them will be described in detail below.

(Basic Form of the Photovoltaic Cell)

In a basic form of the photovoltaic cell of the present invention, the photovoltaic cell comprises a pair of electrodes, at least one of which is transparent or translucent, and a bulk hetero type organic active layer formed from an organic composition of a p-type semiconductor material (an electron-donor compound) and an n-type semiconductor material (an electron-acceptor compound). The organic active layer is formed by film deposition using a solution comprising a p-type semiconductor material, an n-type semiconductor material and a solvent, and the solvent is selected such that each of the SP values of the p-type semiconductor material and the n-type semiconductor material has a certain difference from the SP value of the solvent.

(Basic Action of the Photovoltaic Cell)

The energy of light incident from the transparent or translucent electrode is absorbed by the n-type semiconductor material such as a fullerene derivative and/or the p-type semiconductor material such as a conjugated macromolecular compound to generate excitons in which electrons and holes are bonded to each other by Coulomb coupling. When the generated excitons move and reach a heterojunction interface where the electron-acceptor compound and the electron-donor compound are adjacent to each other, electrons and holes are separated due to a difference in each of HOMO (highest occupied molecular orbital) energy and LOMO (lowest unoccupied molecular orbital) energy at the interface to generate charges that can move independently (electrons and holes). Each of the generated charges can be extracted outside as electric energy (current) by moving toward the respective electrode.

(Substrate)

The photovoltaic cell of the present invention is usually formed on a substrate. The substrate may be any substrate as long as it does not undergo chemical change when electrodes and an organic layer are formed. Examples of materials for the substrate may include glass, plastic, macromolecular film, and silicon. When an opaque substrate is used, the opposite electrode (i.e., the electrode located farther from the substrate) is preferably transparent or translucent.

(Electrodes)

Materials for the transparent or translucent electrode may include a conductive metal oxide film and a translucent metal thin film. Specifically, a film made of conductive materials such as indium oxide, zinc oxide, tin oxide, and composites thereof, e.g., indium tin oxide (ITO), indium zinc oxide (IZO) and NESA; gold; platinum; silver; and copper are used. Among these electrode materials, ITO, indium zinc oxide, and tin oxide are preferred. Examples of methods for manufacturing electrodes may include a vacuum deposition method, a sputtering method, an ion plating method, and a plating method. For the electrode materials, organic transparent conductive films such polyaniline and derivatives thereof, and polythiophene and derivatives thereof may also be used.

The other electrode is not necessarily transparent, and electrode materials such as metals and conductive macromolecules may be used for the electrode. Specific examples of materials for the electrode may include metals such as lithium, sodium, potassium, rubidium, cesium, magnesium, calcium, strontium, barium, aluminum, scandium, vanadium, zinc, yttrium, indium, cerium, samarium, europium, terbium and ytterbium; alloys of two or more of these metals; alloys of one or more of these metals with one or more metals selected from the group consisting of gold, silver, platinum, copper, manganese, titanium, cobalt, nickel, tungsten, and tin; graphite; graphite intercalation compounds; polyaniline and derivatives thereof; and polythiophene and derivatives thereof. Examples of alloys may include a magnesium-silver alloy, a magnesium-indium alloy, a magnesium-aluminum alloy, an indium-silver alloy, a lithium-aluminum alloy, a lithium-magnesium alloy, a lithium-indium alloy, and a calcium-aluminum alloy.

(Intermediate Layer)

Additional intermediate layers (such as charge transport layer) other than the organic photoactive layer may be used as a means of improving photovoltaic efficiency. Materials for use as the intermediate layers may include halides or oxides of alkali metals or alkaline earth metals such as lithium fluoride. Fine particles of inorganic semiconductors such as titanium oxide, and PEDOT (poly-3,4-ethylenedioxythiophene) may also be used.

(Organic Active Layer)

The organic active layer included in the organic photovoltaic cell of the present invention comprises a p-type semiconductor material and an n-type semiconductor material, and can be obtained by film deposition using a solution in which these materials are dissolved in a solvent.

When the organic active layer is formed using a solution comprising one type of p-type semiconductor material (a first p-type semiconductor material), one type of n-type semiconductor material and a solvent, the first p-type semiconductor material, the n-type semiconductor material and the solvent are selected such that the difference between the solubility parameter of the first p-type semiconductor material and the solubility parameter of the solvent is from 2.9 to 6.5, and the difference between the solubility parameter of the n-type semiconductor material and the solubility parameter of the solvent is from 0 to 5.

When a second p-type semiconductor material is additionally used as the p-type semiconductor material, the first p-type semiconductor material, the n-type semiconductor material and the solvent are selected such that the difference between the solubility parameter of the second p-type semiconductor material and the solubility parameter of the solvent is from 2.8 to 6.5.

In addition, when two p-type semiconductor materials are used as the p-type semiconductor material, the weight of the second p-type semiconductor material is preferably adjusted to be 50 or less when the total weight of the p-type semiconductor materials is taken as 100.

As mentioned above, when a bulk hetero type organic active layer is obtained by using a solution comprising the p-type semiconductor material, the n-type semiconductor material and the solvent, setting the differences between the SP values of the above-mentioned three components to predetermined ranges enables to select the most suitable solvent to obtain a bulk hetero type active layer with the most suitable phase separation structure, i.e., a bulk hetero type active layer with increased total volume of an interfacial region between the p-type region and the n-type region (electron and hole transfer pass region).

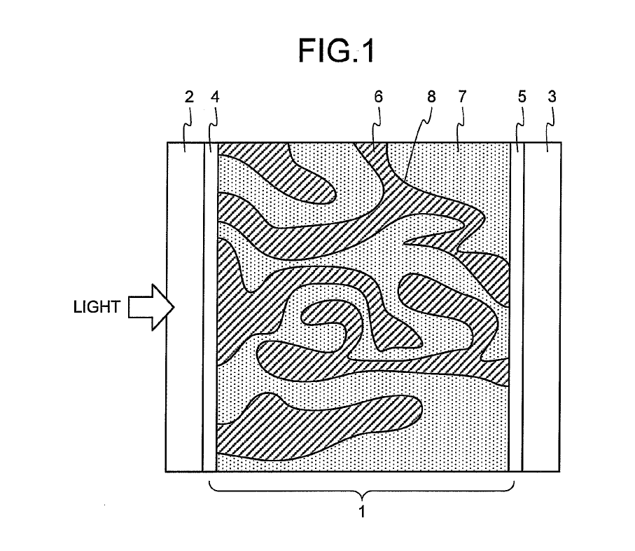

The improvement in photovoltaic efficiency by increasing the total volume of the interfacial region between the p-type region and the n-type region will be illustrated in reference with FIG. 1.

FIG. 1 is a schematic view showing the phase separation structure of the bulk hetero type active layer. FIG. 1 shows a cross sectional structure of a common organic photovoltaic cell having the bulk hetero type active layer 1. The organic active layer 1 is formed between a transparent first electrode (for example, an anode) 2 and a second electrode (for example, a cathode). A first intermediate layer 4 such as a hole transport layer is provided between the organic active layer 1 and the first electrode (anode) 2 as necessary, and a second intermediate layer 5 such as an electron transport layer is provided between the organic active layer 1 and the second electrode (for example, a cathode) as necessary.

In the bulk hetero type organic active layer 1, the p-type region 6 comprising the p-type semiconductor material and the n-type region 7 comprising the n-type semiconductor material form a region (phases) of fine and complicated shape extending from one electrode 2 side to the other electrode 3 side, and are separated from each other via an interfacial region 8 of complicated shape.

When light entered from the transparent electrode side and is incident on the organic active layer 1, excitons (Coulomb-correlated electron-hole pairs) are generated in each of the n-type region 6 and the p-type region 7. When the generated excitons move and reach the interfacial region (depletion layer) 8, electrons and holes are separated due to a difference in HOMO energy and LOMO energy of each of the p-type region 6 and the n-type region 7 in the interfacial region 8 to generate charges that can move independently (electrons and holes). The generated electrons move through the interfacial region 8 as a transfer pass to the cathode 3, while the generated holes move through the interfacial region 8 as a transfer pass to the anode 2. As a result, photovoltage is generated in an organic photovoltaic cell.

Accordingly, when large numbers of the p-type region 6 and the n-type region 7 are formed per unit volume of the organic active layer 1, and each of them is in contact with the electrodes 2 or 3 or the intermediate layers 4 or 5 formed as necessary, and the shape of the interfacial region 8 is more complicated, more excitons generated by light energy can be converted to photovoltage. The most suitable phase separation structure as used herein means that the p-type region 6 and the n-type region 7 are of the above-mentioned shape and form.

In the present invention, when a bulk hetero type organic active layer is obtained by using a solution comprising a p-type semiconductor material, an n-type semiconductor material and a solvent, setting the differences between the SP values of the above-mentioned three components to predetermined ranges enables to select the most suitable solvent to obtain a bulk hetero type active layer with the most suitable phase separation structure.

Accordingly, when a desired p-type and n-type semiconductor materials are selected on the basis of light absorption wavelength range required for an intended cell, the most suitable solvent can be selected to obtain a bulk hetero type active layer with the most suitable phase separation structure. This effect can be achieved when two or more materials are used as the p-type semiconductor material. Therefore, even when two or more p-type semiconductor materials having different light absorption edge wavelengths are selected in order to widen light absorption wavelength range for improved photovoltaic efficiency, the most suitable solvent can be selected, which allows preparation of a bulk hetero type active layer with the most suitable phase separation.

Specific materials for the p-type semiconductor material, the n-type semiconductor material, and the solvent will be described below, and their selection is based on the predetermined differences between the SP values as described above.

(P-Type Semiconductor Materials)

P-type semiconductor materials are electron-donor compounds and may include p-type semiconductor polymers such as pyrazoline derivatives, arylamine derivatives, stilbene derivatives, triphenyldiamine derivatives, oligothiophene and derivatives thereof, polyvinyl carbazole and derivatives thereof, polysilane and derivatives thereof, polysiloxane derivatives having an aromatic amine in the side chain or main chain thereof, polyaniline and derivatives thereof, polythiophene and derivatives thereof, polypyrrole and derivatives thereof, polyphenylene vinylene and derivatives thereof, and polythienylene vinylene and derivatives thereof.

In addition, an organic macromolecular compound having a structural unit indicated by the structural formula (1) below may be mentioned as a preferred p-type semiconductor polymer.

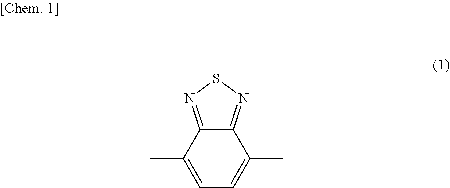

For the organic macromolecular compound, a copolymer of a compound having the structural unit indicated by the structural formula (1) and a compound having a structural unit indicated by the structural formula (2) below is used more preferably.

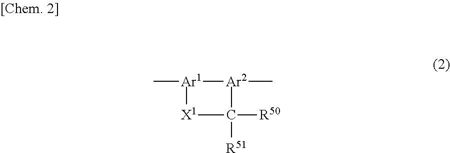

wherein Ar¹ and Ar², which are the same as or different from each other, represent a trivalent heterocyclic group; X¹ represents —O—, —S—, —C(═O)—, —S(═O)—, —SO₂—, —Si(R³) (R⁴)—, —N(R⁵)—, —B(R⁶)—, —P(R⁷)—, or —P(═O) (R⁸)—; R³, R⁴, R⁵, R⁶, R⁷ and R⁸, which are the same as or different from each other, each represents a hydrogen atom, a halogen atom, an alkyl group, an alkyloxy group, an alkylthio group, an aryl group, an aryloxy group, an arylthio group, an arylalkyl group, an arylalkyloxy group, an arylalkylthio group, an acyl group, an acyloxy group, an amido group, an acid imido group, an amino group, a substituted amino group, a substituted silyl group, a substituted silyloxy group, a substituted silylthio group, a substituted silylamino group, a monovalent heterocyclic group, a heterocyclyloxy group, a heterocyclylthio group, an arylalkenyl group, an arylalkynyl group, a carboxyl group, or a cyano group; R⁵⁰ represents a hydrogen atom, a halogen atom, an alkyl group, an alkyloxy group, an alkylthio group, an aryl group, an aryloxy group, an arylthio group, an arylalkyl group, an arylalkyloxy group, an arylalkylthio group, an acyl group, an acyloxy group, an amido group, an acid imido group, an amino group, a substituted amino group, a substituted silyl group, a substituted silyloxy group, a substituted silylthio group, a substituted silylamino group, a monovalent heterocyclic group, a heterocyclyloxy group, a heterocyclylthio group, an arylalkenyl group, an arylalkynyl group, a carboxyl group, or a cyano group; R⁵¹ represents an alkyl group having 6 or more carbon atoms, an alkyloxy group having 6 or more carbon atoms, an alkylthio group having 6 or more carbon atoms, an aryl group having 6 or more carbon atoms, an aryloxy group having 6 or more carbon atoms, an arylthio group having 6 or more carbon atoms, an arylalkyl group having 7 or more carbon atoms, an arylalkyloxy group having 7 or more carbon atoms, an arylalkylthio group having 7 or more carbon atoms, an acyl group having 6 or more carbon atoms, or an acyloxy group having 6 or more carbon atoms; and X¹ and Ar² are bonded to adjacent atoms on the heterocycle contained in Ar¹, and C(R⁵⁰)(R⁵¹) and Ar¹ are bonded to adjacent atoms on the heterocycle contained in Ar².

Specific examples of the copolymer are a macromolecular compound A, which is a copolymer of the two compounds indicated by the structural formula (3), and a macromolecular compound B indicated by the structural formula (4).

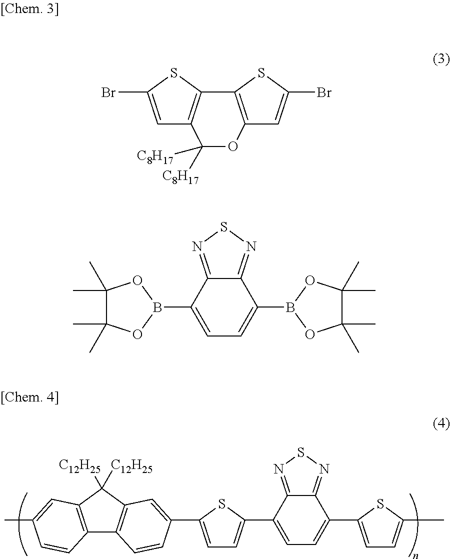

(N-Type Semiconductor Materials)

N-type semiconductor materials are electron-acceptor compounds and examples thereof may include oxadiazole derivatives, anthraquinodimethane and derivatives thereof, benzoquinone and derivatives thereof, naphthoquinone and derivatives thereof, anthraquinone and derivatives thereof, tetracyanoanthraquinodimethane and derivatives thereof, fluorenone derivatives, diphenyldicyanoethyelene and derivatives thereof, diphenoquinone derivatives, metal complexes of 8-hydroxyquinoline and of derivatives thereof, polyquinoline and derivatives thereof, polyquinoxaline and derivatives thereof, polyfluorene and derivatives thereof, fullerenes such as C₆₀ and derivatives thereof, phenanthrene derivatives such as bathocuproine, metal oxides such as titanium oxide, and carbon nanotubes. Preferred electron-acceptor compounds are titanium oxide, carbon nanotubes, fullerene, and fullerene derivatives, and especially preferred electron-acceptor compounds are fullerene and fullerene derivatives.

Examples of the fullerene may include C₆₀ fullerene, C₇₀ fullerene, C₇₆ fullerene, C₇₈ fullerene, and C₈₄ fullerene.

Examples of fullerene derivatives may include C₆₀ fullerene derivatives, C₇₀ fullerene derivatives, C₇₆ fullerene derivatives, C₇₈ fullerene derivatives, and C₈₄ fullerene derivatives. Specific structures of the fullerene derivatives are as follows.

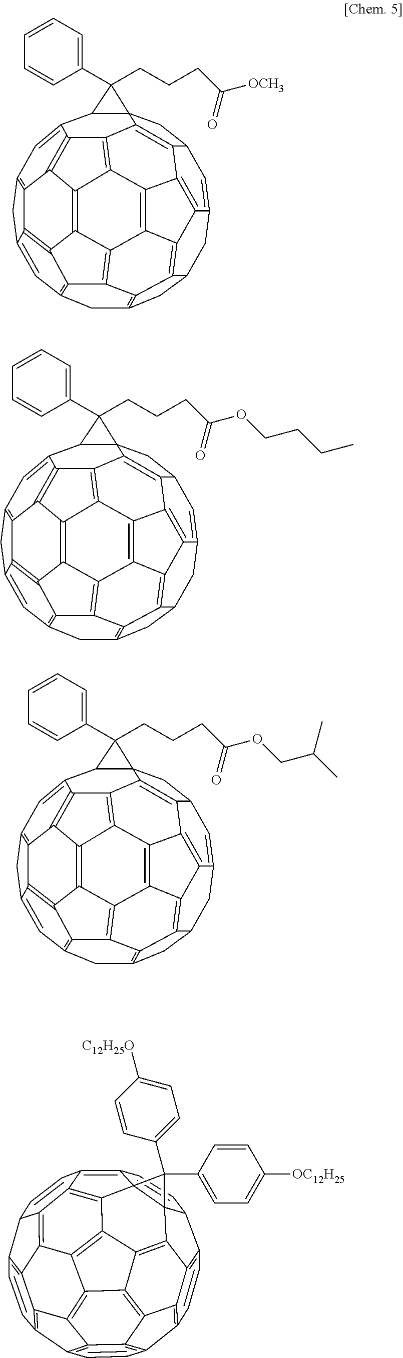

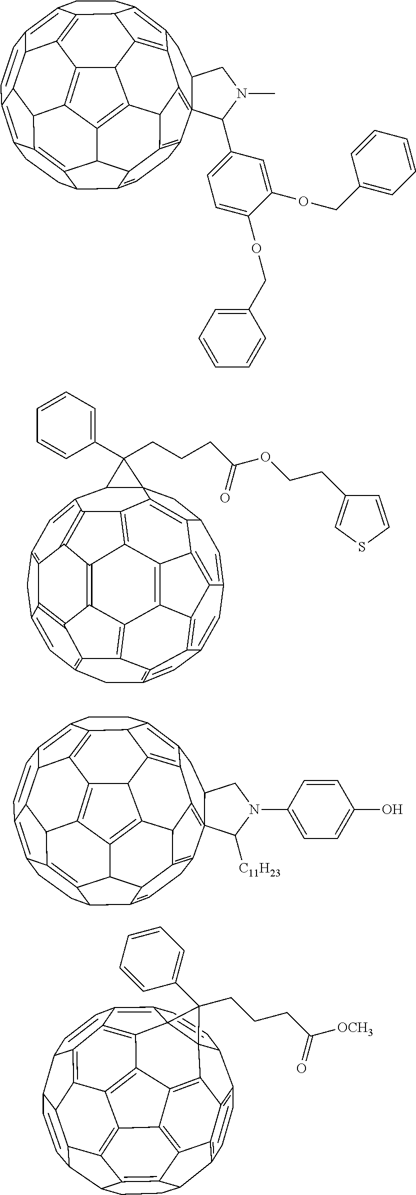

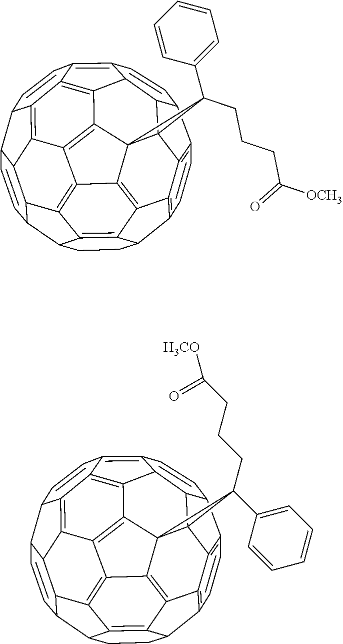

Examples of the fullerene derivatives may include [6,6]-phenyl C61 butyric acid methyl ester (C60PCBM), [6,6]-phenyl C71 butyric acid methyl ester (C70PCBM), [6,6]-phenyl C85 butyric acid methyl ester (C84PCBM), and [6,6]-thienyl C61 butyric acid methyl ester.

When the fullerene derivative is used as the n-type semiconductor material, the fullerene derivative is used preferably in a ratio of from 10 to 1000 parts by weight, more preferably from 20 to 500 parts by weight, per 100 parts by weight of electron-donor compound.

Usually, the thickness of the organic photoactive layer is preferably from 1 nm to 100 μm, more preferably from 2 nm to 1000 nm, further preferably from 5 nm to 500 nm, even more preferably from 20 nm to 200 nm.

(Method for Manufacturing an Organic Active Layer)

In the present invention, the organic photoactive layer is of bulk hetero type and can be formed by film deposition using a solution comprising the p-type semiconductor material, the n-type semiconductor material and the solvent.

A solvent used for film deposition using a solution is not particularly limited as long as the solvent can dissolve the p-type semiconductor material and the n-type semiconductor material, and the differences between the SP value of the solvent and each of the SP values of the p-type semiconductor material and the n-type semiconductor material fall within the predetermined ranges as described above.

Examples of such candidate solvents may include unsaturated hydrocarbon solvents such as toluene, xylene, mesitylene, tetralin, decalin, bicyclohexyl, n-butylbenzene, sec-butylbenzene and tert-butylbenzene; halogenated saturated hydrocarbon solvents such as tetrachlorocarbon, chloroform, dichloromethane, dichloroethane, chlorobutane, bromobutane, chloropentane, bromopentane, chlorohexane, bromohexane, chlorocyclohexane and bromocyclohexane; halogenated unsaturated hydrocarbon solvents such as chlorobenzene, dichlorobenzene and trichlorobenzene; ether solvents such as tetrahydrofuran and tetrahydropyran. Usually, the above-mentioned p-type and n-type semiconductor materials can be dissolved in the solvent in an amount of 0.1% by weight or more.

For the film deposition, applying methods may be used, such as a spin coating method, a casting method, a micro gravure coating method, a gravure coating method, a bar coating method, a roll coating method, a wire-bar coating method, a dip coating method, a spray coating method, a screen printing method, a gravure printing method, a flexo printing method, an offset printing method, an inkjet printing method, a dispenser printing method, a nozzle coating method, and a capillary coating method. Among the above applying methods, a spin coating method, a flexo printing method, a gravure printing method, an inkjet printing method, and a dispenser printing method are preferred.

(Application of Cells)

The photovoltaic cell of the present invention can be operated as an organic thin film solar cell when it is irradiated with light such as sunlight from transparent or translucent electrode to generate a photovoltaic force between the electrodes. It is also possible to use as an organic thin film solar cell module by integrating a plurality of organic thin film solar cells.

It is also possible to operate as an organic optical sensor when a photocurrent flows by irradiation with light from transparent or translucent electrode in a state where a voltage is applied or not applied between the electrodes. It is possible to use an organic image sensor by integrating a plurality of organic optical sensors.

(Solar Cell Module)

The organic thin film solar cell may basically have the same module structure as that of a conventional solar cell module. The solar cell module usually has a structure in which cells are formed on a supporting substrate, such as metal, and ceramic, and covered with a filler resin, a protective glass or the like, and thus light is captured from the opposite side of the supporting substrate. The solar cell module may also have a structure in which a transparent material such as a reinforced glass is used as the material of a supporting substrate and cells are formed thereon, and thus light is captured from the side of the transparent supporting substrate. Specifically, known examples of the structure of the solar cell module may include module structures such as a superstraight type, a substrate type, and a potting type; and a substrate-integrated module structure used in an amorphous silicon solar cell. The solar cell module using the organic photovoltaic cell of the present invention may appropriately select a suitable module structure depending on an intended purpose, place, environment, and the like.

In a typical superstraight type or substrate type module, cells are arranged at certain intervals between a pair of supporting substrates. One or both of the supporting substrates are transparent and are subjected to antireflection-treatment. The adjacent cells are connected to each other through wiring such as a metal lead and a flexible wiring, and an current collecting electrode is placed at an external peripheral portion of the module for extracting electric power generated in the cell to the exterior. Between the substrate and the cell, various types of plastic materials such as ethylene vinyl acetate (EVA) may be used in the form of a film or a filler resin in order to protect the cell and to improve the electric current collecting efficiency. When the module is used at a place where its surface needs not to be covered with a hard material, for example, at a place unlikely to suffer from impact from outside, one of the supporting substrates can be omitted by forming a surface protective layer with a transparent plastic film or curing the filler resin to impart a protective function. The periphery of the supporting substrate is fixed with a frame made of metal in a sandwich shape so as to seal the inside and to secure rigidity of the module. A space between the supporting substrate and the frame is sealed with a sealing material. A solar cell can also be formed on a curved surface when a flexible material is used for the cell per se, the supporting substrate, the filler material and the sealing material.

In the case of a solar cell with a flexible substrate such as a polymer film, a cell body can be manufactured by sequentially forming cells while feeding a roll-shaped substrate, cutting into a desired size, and then sealing a peripheral portion with a flexible and moisture-resistant material. It is also possible to employ a module structure called “SCAF” described in Solar Energy Materials and Solar Cells, 48, p. 383-391. Furthermore, a solar cell with a flexible substrate can also be used in a state of being adhesively bonded to a curved glass or the like.

### EXAMPLES

Examples of the present invention will be illustrated below. The following examples are merely exemplary to illustrate the present invention, and not to intend to limit the present invention.

### Example 1

### Formation of Transparent Substrate-Transparent Anode-Hole Transport Layer

A transparent glass substrate having on its surface a transparent electrode (anode) prepared by sputtering ITO to a film thickness of about 150 nm and patterning the ITO was prepared. The glass substrate was washed with an organic solvent, an alkali detergent and ultrapure water, and dried. The dried substrate was subjected to UV-O₃ treatment with a UV ozone apparatus (UV-O₃ apparatus, manufactured by TECHNOVISION INC., model “UV-312”).

A suspension of poly(3,4)ethylenedioxythiophene/polystyrene sulfonic acid (manufactured by H.C. Starck-V TECH Ltd., under the trade name of “Bytron P TP AI 4083”) as a hole transport layer material was prepared and filtrated through a filter having a pore size of 0.5 micron. The filtrated suspension was applied on the transparent electrode side of the substrate by spin coating to form a film in a thickness of 70 nm. The resultant film was dried on a hotplate at 200° C. for 10 minutes under atmospheric environment, thus forming a hole transport layer on the transparent electrode.

### Formation of Organic Active Layer

Next, a solution of two electron-donor macromolecular materials (p-type semiconductor materials), i.e., the macromolecular compound A which is an electron-donor compound represented by the structural formula (3) below (a first p-type semiconductor polymer) and poly(3-hexylthiophene) (P3HT) (a second p-type semiconductor polymer), and [6,6]-phenyl C61 butyric acid methyl ester ([6,6]-PCBM) which is an electron-acceptor compound (an n-type semiconductor material) in a weight ratio of 2:1:4 in ortho-dichlorobenzene was prepared. The concentration of the macromolecular compound A in the solution was 0.5% by weight.

The prepared solution was spin-coated on the surface of the hole transport layer on the substrate and then dried under an N₂ atmosphere. A bulk hetero type organic active layer was thus formed on the hole transport layer.

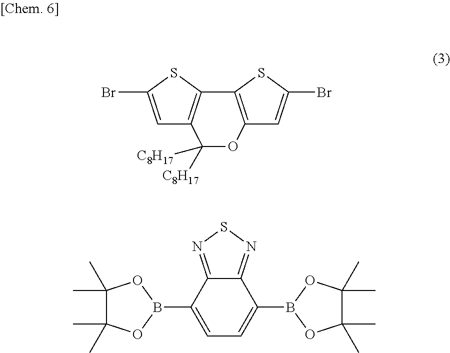

The macromolecular compound A, which is a copolymer of two compounds represented by the structural formula (3), had a polystyrene-equivalent weight average molecular weight of 17000 and a polystyrene-equivalent number average molecular weight of 5000. The macromolecular polymer A had a light absorption edge wavelength of 925 nm.

The components of the organic active layer were set as follows.

Because selection of a solvent strongly influences formation of electron and hole transfer passes in the active layer, i.e., a phase separation structure of pn semiconductors, the phase separation structure was controlled in terms of the SP values. The solubility of the macromolecular compound A is very high, and the SP value of PCBM, which is the n-type semiconductor material, and the SP value of the solvent are close; therefore, ortho-dichlorobenzene was selected for the solvent so that the difference between the SP value of the solvent and the SP value of the macromolecular compound A, which is the p-type semiconductor material, falls within a certain range.

To obtain the most suitable phase separation, the difference between the SP value of the first p-type semiconductor material and the SP value of the solvent needs to be from 2.9 to 6.5, the difference between the SP value of the second p-type semiconductor material and the SP value of the solvent needs to be from 2.8 to 6.5, and the difference between the SP value of the n-type semiconductor material and the SP value of the solvent needs to be from 0 to 5.

Among the candidate solvents, the SP value of chlorobenzene is 19.58, the SP value of xylene is 18.05, the SP value of toluene is 18.30, the SP value of chloroform is 18.81, whereas the SP value of ortho-dichlorobenzene is 20.72.

The difference between the SP value of the macromolecular compound A, which is the first p-type semiconductor material, and the SP value of ortho-dichlororobenzene falls within a range from 2.9 to 6.5, the SP value of P3HT that is the second p-type semiconductor material is 16.80, and the SP value of C60PCBM that is the n-type semiconductor material is 22.45. The SP value of ortho-dichlorobenzene is 20.72. Accordingly, ortho-dichlorobenzene was selected as the most suitable solvent.

### Formation of Electron Transport Layer-Cathode and Sealing Treatment

Finally, the substrate was placed in a resistance heating evaporation apparatus. LiF was deposited on the organic active layer in a film thickness of about 2.3 nm to form an electron transport layer, and then Al was deposited thereon in a film thickness of about 70 nm to form a cathode. Thereafter, a sealing treatment was conducted by adhesively bonding a glass substrate to the cathode with using an epoxy resin (fast-setting Araldite) as a sealing material, thus obtaining an organic photovoltaic cell.

The obtained photovoltaic cell had a shape of square measuring 2 mm by 2 mm.

### Example 2

### Formation of Transparent Substrate-Transparent Anode-Hole Transport Layer

A transparent glass substrate having on its surface a transparent electrode (anode) prepared by sputtering ITO to a film thickness of about 150 nm and patterning the ITO was prepared. The glass substrate was washed with an organic solvent, an alkali detergent and ultrapure water, and dried. The dried substrate was subjected to UV-O₃ treatment with a UV ozone apparatus (UV-O₃ apparatus, manufactured by TECHNOVISION INC., model “UV-312”).

A suspension of poly(3,4)ethylenedioxythiophene/polystyrene sulfonic acid (manufactured by H.C. Starck-V TECH Ltd., under the trade name of “Bytron P TP AI 4083”) as a hole transport layer material was prepared and filtrated through a filter having a pore size of 0.5 micron. The filtrated suspension was applied on the transparent electrode side of the substrate by spin coating to form a film in a thickness of 70 nm. The resultant film was dried on a hotplate at 200° C. for 10 minutes under atmospheric environment, thus forming a hole transport layer on the transparent electrode.

### Formation of Organic Active Layer)

Next, a solution of two electron-donor macromolecular materials (p-type semiconductor materials), i.e., the macromolecular compound B which is an electron-donor compound represented by the structural formula (4) below (a first p-type semiconductor polymer) and poly(3-hexylthiophene) (P3HT) (a second p-type semiconductor polymer), and [6,6]-phenyl C61 butyric acid methyl ester ([6,6]-PCBM) which is an electron-acceptor compound (an n-type semiconductor material) in a weight ratio of 2:1:4 in ortho-dichlorobenzene was prepared. The concentration of the macromolecular compound B in the solution was 0.5% by weight.

The prepared solution was spin-coated on the surface of the hole transport layer on the substrate and then dried under an N₂ atmosphere. A bulk hetero type organic active layer was thus formed on the hole transport layer.

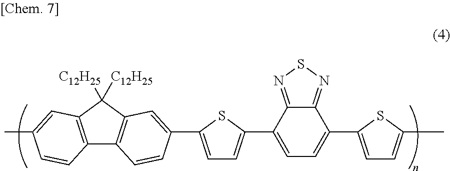

The macromolecular compound B represented by the structural formula (4) had a polystyrene-equivalent weight average molecular weight of 17887 and a polystyrene-equivalent number average molecular weight of 5000. The macromolecular polymer A had a light absorption edge wavelength of 645 nm.

The components of the organic active layer were set as follows.

To obtain the most suitable phase separation structure, the difference between the SP value of the first p-type semiconductor material and the SP value of the solvent needs to be from 2.9 to 6.5, the difference between the SP value of the second p-type semiconductor material and the SP value of the solvent needs to be from 2.8 to 6.5, and the difference between the SP value of the n-type semiconductor material and the SP value of the solvent needs to be from 0 to 5.

Among the candidate solvents, the SP value of chlorobenzene is 19.58, the SP value of xylene is 18.05, the SP value of toluene is 18.30, the SP value of chloroform is 18.81, whereas the SP value of ortho-dichlorobenzene is 20.72.

The SP value of the macromolecular compound B, which is the p-type semiconductor material, is 16.70, the SP value of P3HT, which is another p-type semiconductor material, is 16.80, and the SP value of C60PCBM, which is the n-type semiconductor material, is 22.45. The SP value of ortho-dichlorobenzene is 20.72. Accordingly, ortho-dichlorobenzene was selected as the most suitable solvent.

### Formation of Electron Transport Layer-Cathode and Sealing Treatment

Finally, the substrate was placed in a resistance heating evaporation apparatus. LiF was deposited on the organic active layer in a film thickness of about 2.3 nm to form an electron transport layer, and then Al was deposited thereon in a film thickness of about 70 nm to form a cathode. Thereafter, a sealing treatment was conducted by adhesively bonding a glass substrate to the cathode with using an epoxy resin (fast-setting Araldite) as a sealing material, thus obtaining an organic photovoltaic cell.

The obtained photovoltaic cell had a shape of square measuring 2 mm by 2 mm.

### Example 3

### Formation of Transparent Substrate-Transparent Anode-Hole Transport Layer

A transparent glass substrate having on its surface a transparent electrode (anode) prepared by sputtering ITO to a thickness of about 150 nm and patterning the ITO was prepared. The glass substrate was washed with an organic solvent, an alkali detergent and ultrapure water, and dried. The dried substrate was subjected to UV-O₃ treatment with a UV ozone apparatus (UV-O₃ apparatus, manufactured by TECHNOVISON INC., model “UV-312”).

A suspension of poly(3,4)ethylenedioxythiophene/polystyrene sulfonic acid (manufactured by H.C. Starck-V TECH Ltd., under the trade name of “Bytron P TP AI 4083”) as a hole transport layer material was prepared and filtrated through a filter having a pore size of 0.5 micron. The filtrated suspension was applied on the transparent electrode side of the substrate by spin coating to form a film in a thickness of 70 nm. The resultant film was dried on a hot plate at 200° C. for 10 minutes under atmospheric environment, thus forming a hole transport layer on the transparent electrode.

### Formation of Organic Active Layer

Next, a solution of poly(3-hexylthiophene) (P3HT) that is an electron-donor compound (a first p-type semiconductor material) and [6,6]-phenyl C61 butyric acid methyl ester ([6,6]-PCBM) that is an electron-acceptor compound (an n-type semiconductor material) in a weight ratio of 1:0.8 in ortho-dichlorobenzene was prepared.

The prepared solution was spin-coated on the surface of the hole transport layer on the substrate and then dried under an N₂ atmosphere. A bulk hetero type organic active layer was thus formed on the hole transport layer.

The components of the organic active layer were set as follows.

To obtain the most suitable phase separation, the difference between the SP value of the first p-type semiconductor material and the SP value of the solvent needs to be from 2.9 to 6.5, and the difference between the SP value of the n-type semiconductor material and the SP value of the solvent needs to be from 0 to 5.

Among the candidate solvents, the SP value of chlorobenzene is 19.58, the SP value of xylene is 18.05, the SP value of toluene is 18.30, the SP value of chloroform is 18.81, whereas the SP value of ortho-dichlorobenzene is 20.72.

The SP value of P3HT, which is the p-type semiconductor material, is 16.80, and the SP value of C60PCBM, which is the n-type semiconductor material is 22.45. The SP value of ortho-dichlorobenzene is 20.72. Accordingly, ortho-dichlorobenzene was selected as the most suitable solvent.

### Formation of Electron Transport Layer-Cathode and Sealing Treatment

Finally, the substrate was placed in a resistance heating evaporation apparatus. LiF was deposited on the organic active layer in a film thickness of about 2.3 nm to form an electron transport layer, and then Al was deposited thereon in a film thickness of about 70 nm to form a cathode. Thereafter, a sealing treatment was conducted by adhesively bonding a glass substrate to the cathode with using an epoxy resin (fast-setting Araldite) as a sealing material, thus obtaining an organic photovoltaic cell.

The obtained photovoltaic cell had a shape of square measuring 2 mm by 2 mm.

### Example 4

### Formation of Transparent Substrate-Transparent Anode-Hole Transport Layer

A transparent glass substrate having on its surface a transparent electrode (anode) prepared by sputtering ITO to a thickness of about 150 nm and patterning the ITO was prepared. The glass substrate was washed with an organic solvent, an alkali detergent and ultrapure water, and dried. The dried substrate was subjected to UV-O₃ treatment with a UV ozone apparatus (UV-O₃ apparatus, manufactured by TECHNOVISON INC., model “UV-312”).

A suspension of poly(3,4)ethylenedioxythiophene/polystyrene sulfonic acid (manufactured by H.C. Starck-V TECH Ltd., under the product name “Bytron P TP AI 4083”) as a hole transport layer material was prepared and filtrated through a filter having 0.5 micron. The filtrated suspension was applied on the transparent electrode side of the substrate by spin coating to form a film in a thickness of 70 nm. The resultant film was dried on a hot plate at 200° C. for 10 minutes under atmospheric environment, thus forming a hole transport layer on the transparent electrode.

### Formation of Organic Active Layer

Next, a solution of two electron-donor macromolecular materials (p-type semiconductor materials), i.e., poly(2-methoxy-5-(2′-ethylhexyloxy)-1,4-phenylene vinylene) (MEH-PPV), which is an electron-donor compound (a first p-type semiconductor polymer), and poly(3-hexylthiophene) (P3HT) (a second p-type semiconductor polymer), and [6,6]-phenyl-C61 butyric acid methyl ester ([6,6]-PCBM) which is an electron-acceptor material (an n-type semiconductor material) in a weight ratio of 2:1:4 in ortho-dichlorobenzene was prepared. The concentration of MEH-PPV in the solution was 0.5% by weight.

The prepared solution was spin-coated on the surface of the hole transport layer on the substrate and then dried under an N₂ atmosphere. A bulk hetero type organic active layer was thus formed on the hole transport layer.

The components of the organic active layer were set as follows.

To obtain the most suitable phase separation, the difference between the SP value of the first p-type semiconductor material and the SP value of the solvent needs to be from 2.9 to 6.5, the difference between the SP value of the second p-type semiconductor material and the SP value of the solvent needs to be from 2.8 to 6.5, and the difference between the SP value of the n-type semiconductor material and the SP value of the solvent needs to be from 0 to 5.

Among the candidate solvents, the SP value of chlorobenzene is 19.58, the SP value of xylene is 18.05, the SP value of toluene is 18.30, the SP value of chloroform is 18.81, whereas the SP value of ortho-dichlorobenzene is 20.72.

The difference between the SP value of poly(2-methoxy-5-(2′-ethylhexyloxy)-1,4-phenylene vinylene) (MEH-PPV), which is the first p-type semiconductor material, and the SP value of ortho-dichlorobenzene falls within a range from 2.9 to 6.5, the SP value of P3HT, which is the second p-type semiconductor material, is 16.80, and the SP value of C60PCBM, which is the n-type semiconductor material, is 22.45. The SP value of ortho-dichlorobenzene is 20.72. Accordingly, ortho-dichlorobenzene was selected as the most suitable solvent.

### Formation of Electron Transport Layer-Cathode and Sealing Treatment

Finally, the substrate was placed in a resistance heating evaporation apparatus. LiF was deposited on the organic active layer in a film thickness of about 2.3 nm to form an electron transport layer, and then Al was deposited thereon in a film thickness of about 70 nm to form a cathode. Thereafter, a sealing treatment was conducted by adhesively bonding a glass substrate to the cathode with using an epoxy resin (fast-setting Araldite) as a sealing material, thus obtaining an organic photovoltaic cell.

The obtained photovoltaic cell had a shape of square measuring 2 mm by 2 mm.

### Comparative Example 1

An organic photovoltaic cell was prepared in the same manner as Example 1 except that chlorobenzene was used for the solvent instead of ortho-dichlorobenzene.

### Comparative Example 2

An organic photovoltaic cell was prepared in the same manner as Example 2 except that chlorobenzene was used for the solvent instead of ortho-dichlorobenzene.

### Comparative Example 3

An organic photovoltaic cell was prepared in the same manner as Example 3 except that chlorobenzene was used for the solvent instead of ortho-dichlorobenzene.

### Comparative Example 4

An organic photovoltaic cell was prepared in the same manner as Example 4 except that chlorobenzene was used for the solvent instead of ortho-dichlorobenzene.

### Evaluation of Photovoltaic Characteristics of Photovoltaic Cells

The photovoltaic properties of the photovoltaic cells obtained in Examples 1 to 4 and Comparative Examples 1 to 4 were evaluated as follows.

The obtained photovoltaic cell (presumed as an organic thin film solar cell: a shape of square measuring 2 mm by 2 mm) was irradiated with a certain amount of light using a solar simulator (manufactured by BUNKOKEIKI Co., Ltd, under the trade name of “model CEP-2000”, irradiance: 100 mW/cm²) to measure the generated current and voltage. The measurements were calculated to obtain photovoltaic efficiency (%) and short-circuit current density. The results are shown in Tables 1 and 2 below.

TABLE 1

| | Example 1 | Example 2 | Example 3 | Example 4 |
|---|---|---|---|---|
| Short-circuit current | 7.36 | 6.87 | 2.69 | 2.02 |
| density (mA/cm²) | | | | |
| Photovoltaic | 1.88 | 2.22 | 0.72 | 0.65 |
| efficiency (%) | | | | |

TABLE 2

| | Comparative | Comparative | Comparative | Comparative |
|---|---|---|---|---|
| | Example 1 | Example 2 | Example 3 | Example 4 |
| Short-circuit | 5.86 | 5.67 | 2.64 | 1.55 |
| current density | | | | |
| (mA/cm²) | | | | |
| Photovoltaic | 1.52 | 0.73 | 0.54 | 0.35 |
| efficiency (%) | | | | |

As can be seen in Tables 1 and 2, the photovoltaic efficiency of each of the photovoltaic cells prepared in Examples 1, 2, 3 and 4 was higher than the photovoltaic efficiency and short-circuit current density of the cell prepared in the corresponding Comparative Examples 1, 2, 3 and 4.

### INDUSTRIAL APPLICABILITY

As mentioned above, the photovoltaic cell of the present invention can improve photovoltaic efficiency and is useful in photovoltaic devices such as solar cells and optical sensors, and especially suitable for organic solar cells.

1. An organic photovoltaic cell comprising:
an anode;
a cathode; and
an organic active layer provided between the anode and the cathode and formed by using a solution comprising a first p-type semiconductor material, an n-type semiconductor material and a solvent, wherein
a difference between a solubility parameter of the first p-type semiconductor material and a solubility parameter of the solvent is from 2.9 to 6.5, and a difference between a solubility parameter of the n-type semiconductor material and the solubility parameter of the solvent is from 0 to 5.

2. The organic photovoltaic cell according to claim 1, wherein a second p-type semiconductor material is included as another p-type semiconductor material that constitutes the organic active layer, and a difference between a solubility parameter of the second p-type semiconductor material and the solubility parameter of the solvent is from 2.8 to 6.5.

3. The organic photovoltaic cell according to claim 2, wherein a weight of the second p-type semiconductor material is 50 or less when a total weight of the p-type semiconductor materials included in the organic active layer is taken as 100.

4. A method for manufacturing an organic photovoltaic cell that comprises an anode, a cathode, and an organic active layer provided between the anode and the cathode and formed by using a solution comprising a first p-type semiconductor material, an n-type semiconductor material and a solvent, the method comprising:
selecting the first p-type semiconductor material, the n-type semiconductor material and the solvent such that a difference between a solubility parameter of the first p-type semiconductor material and a solubility parameter of the solvent is from 2.9 to 6.5 and a difference between a solubility parameter of the n-type semiconductor material and the solubility parameter of the solvent is from 0 to 5.

5. The method for manufacturing an organic photovoltaic cell according to claim 4, wherein a second p-type semiconductor material is used as another p-type semiconductor material that constitutes the organic active layer, and the method comprises selecting the first p-type semiconductor material, the second p-type semiconductor material, the n-type semiconductor material and the solvent such that a difference between a solubility parameter of the second p-type semiconductor material and the solubility parameter of the solvent is from 2.8 to 6.5.

6. The method for manufacturing an organic photovoltaic cell according to claim 5, wherein a weight of the second p-type semiconductor material is adjusted to be 50 or less when a total weight of the p-type semiconductor materials included in the organic active layer is taken as 100.
